(19) United States
(12) Patent Application Publication
(10) Pub. No.: US 2026/0307492 A1
(43) Pub. Date: Oct. 8, 2026

(54) DETERMINATION OF A BATTERY CAPABILITY ASSOCIATED WITH A SAFETY FUNCTION

(71) Applicant: CPS Technology Holdings LLC, New York, NY (US)

(72) Inventors: Jin ZHIHONG, Pewaukee, WI (US); Logan CRAIN, Milwaukee, WI (US); Yinghao YU, Brookfield, WI (US)

(21) Appl. No.: 19/476,957

(22) PCT Filed: Apr. 19, 2024
(86) PCT No.: PCT/US2024/025524

§ 371 Date: Oct. 20, 2025

Related U.S. Application Data
(60) Provisional application No. 63/497,310, filed on Apr. 20, 2023.

(51) Int. Cl. B60L 3/00; B60L 58/12; B60L 58/16; G01R 31/367; G01R 31/396; H01M 10/42

(52) U.S. Cl. CPC B60L 3/0046; B60L 58/12; B60L 58/16; G01R 31/367; G01R 31/396; H01M 10/425; H01M 2010/4271

(57) ABSTRACT

A battery management system (BMS) of a battery that has a plurality of cells is described. The BMS is electrically couplable to each cell of the plurality of cells and is configured to determine a capability of the battery to provide one or more output parameters usable for performing a safety function within a predetermined time. The capability is determined based on one or more cell parameters associated at least with one or more cells of the plurality of cells. The BMS is further configured to perform one or more actions based on the determined capability.

### TECHNICAL FIELD

This disclosure relates to batteries, and in particular to a method and system for determination of a battery capability and/or one or more diagnostic processes and/or parameters associated with a safety function.

### BACKGROUND

Motor-powered and/or electrically powered vehicles tend to rely on using one or more battery systems for providing a starting power (e.g., power used to crank and start an engine) and/or at least a portion of a motion power for the vehicle. Such vehicles may include one or more of an air- or watercraft, a rail-guided vehicle, a street vehicle, etc., where a street vehicle may refer to, for example, one or more cars, trucks, buses, recreational vehicles, etc.

In vehicles, different types of batteries (e.g., energy storage modules) are used, such as traction batteries (for electric or hybrid electric vehicles) and starter batteries. In automotive applications, for example, a starter battery is used for providing the necessary energy/power required for starting a vehicle where a traction battery may generally refer to a battery which provides motive power to the vehicle, for example. Further, batteries may be arranged to also provide power to other systems such as accessories and/or accessory systems in a vehicle and/or the battery.

Conventional processes (e.g., algorithms) for detecting battery failures may detect failures after a catastrophic failure of the battery has occurred, e.g., where the battery has reached a condition that does not allow the battery to provide power to perform any functions.

### SUMMARY

Some embodiments advantageously provide a method, apparatus, and system for determining and/or predicting and/or forecasting a capability of the battery to provide output parameters (e.g., a state of function) usable for performing a safety function such as driving the vehicle for a predetermined time, pulling the vehicle over to a safe area, stopping the vehicle, power one or more vehicle systems such as emergency lights, vehicle communication systems (e.g., to make emergency calls, service calls, etc.), air conditioning systems, etc.

According to one aspect, a battery management system (BMS) of a battery that has a plurality of cells is described. The BMS is electrically couplable to each cell of the plurality of cells and is configured to determine a capability of the battery to provide one or more output parameters usable for performing a safety function within a predetermined time. The capability is determined based on one or more cell parameters associated at least with one or more cells of the plurality of cells. The BMS is further configured to perform one or more actions based on the determined capability.

In some embodiments, the BMS is further configured to determine the one or more output parameters of the battery based on the one or more cell parameters associated at least with the one or more cells of the plurality of cells, obtain an output parameter threshold, and compare the determined one or more output parameters to the obtained output parameter threshold to the determine the capability of the battery.

In some other embodiments, the one or more cell parameters include one or more of a battery current, a battery voltage, a cell voltage, a temperature parameter.

In some embodiments, the one or more output parameters includes one or more of a battery current, a battery voltage, a battery temperature, battery state of charge, battery state of health, battery state of function.

In some other embodiments, one or both the capability and the one or more output parameters are determined based on a prediction model.

In some embodiments, the one or more output parameters include a resistance associated with the one or more cells at a predetermined battery temperature, and the BMS is further configured to determine an increase of the resistance over time to determine the capability of the battery.

In some other embodiments, the BMS is further configured to perform a state of function prediction based the one or more cell parameters to determine the capability of the battery.

In some embodiments, the BMS is further configured to one or more of compare a first cell parameter of the one or more cell parameters with a predetermined cell parameter threshold, determine a difference between the first cell parameter and a second cell parameter of the one or more cell parameters, perform the state of function prediction based on one or both of the comparison and the determined difference.

In some other embodiments, the BMS is further configured to determine a correlation between a third cell parameter and a fourth cell parameter of the one or more cell parameters to determine the capability of the battery, where the third cell parameter is associated with a start-up signal, the fourth cell parameter corresponds to performing the safety function, and the correlation is usable to determine the capability of the battery.

In some embodiments, the safety function includes safely pulling over and stopping a vehicle within the predetermined time.

In some other embodiments, the safety function includes using, within the predetermined time, a vehicle system that is electrically couplable to the battery.

In some embodiments, the one or more actions include one or more of identifying a cell that is underperforming, causing recharging of the identified cell 32, and transmitting an indication indicating the capability of the battery.

According to another aspect, a battery comprising battery management system (BMS) and a plurality of cells is described. The BMS is electrically coupled to each cell of the plurality of cells, and the BMS being configured to determine a capability of the battery to provide one or more output parameters usable for performing a safety function within a predetermined time. The capability being determined based on one or more cell parameters associated at least with one or more cells of the plurality of cells. The BMS is also configured to perform one or more actions based on the determined capability.

In some embodiments, one or both the capability and the one or more output parameters are determined based on a prediction model.

In some other embodiments, the one or more output parameters include a resistance associated with the one or more cells at a predetermined battery temperature, and the BMS is further configured to determine an increase of the resistance over time to determine the capability of the battery.

In some embodiments, the BMS is further configured to perform a state of function prediction based the one or more cell parameters to determine the capability of the battery.

In some other embodiments, the BMS is further configured to one or more of compare a first cell parameter of the one or more cell parameters with a predetermined cell parameter threshold, determine a difference between the first cell parameter and a second cell parameter of the one or more cell parameters, and perform the state of function prediction based on one or both of the comparison and the determined difference.

In some embodiments, the BMS is further configured to determine a correlation between a third cell parameter and a fourth cell parameter of the one or more cell parameters to determine the capability of the battery. The third cell parameter is associated with a start-up signal, and the fourth cell parameter corresponds to performing the safety function. The correlation being usable to determine the capability of the battery.

In some other embodiments, the safety function includes, within the predetermined time, one or more of safely pulling over, stopping a vehicle, and using a vehicle system that is electrically couplable to the battery.

In some embodiments, the one or more actions include one or more of identifying a cell that is underperforming, causing recharging of the identified cell, and transmitting an indication indicating the capability of the battery.

According to one aspect, a system comprising a vehicle and a battery positionable within the vehicle is described. The battery includes a battery management system (BMS) and a plurality of cells, where the BMS is electrically coupled to each cell of the plurality of cells. The BMS is configured to determine a capability of the battery to provide one or more output parameters usable for performing a safety function within a predetermined time. The capability is determined based on one or more cell parameters associated at least with one or more cells of the plurality of cells. The BMS is also configured to perform one or more actions based on the determined capability.

In some embodiments, the safety function includes, within the predetermined time, one or more of, safely pulling the vehicle over, stopping the vehicle, and using a vehicle system that is electrically coupled to the battery.

In some other embodiments, the one or more actions include one or more of identifying a cell that is underperforming, causing recharging of the identified cell, and transmitting an indication indicating the capability of the battery.

According to another aspect, a method in a battery management system (BMS) of a battery comprising a plurality of cells is described. The BMS is electrically couplable to each cell of the plurality of cells, and the method includes determining a capability of the battery to provide one or more output parameters usable for performing a safety function within a predetermined time. The capability is determined based on one or more cell parameters associated at least with one or more cells of the plurality of cells. The method also includes performing one or more actions based on the determined capability.

### BRIEF DESCRIPTION OF THE DRAWINGS

A more complete understanding of embodiments described herein, and the attendant advantages and features thereof, will be more readily understood by reference to the following detailed description when considered in conjunction with the accompanying drawings wherein:

FIG. 1 is a diagram of an example system according to principles disclosed herein;

FIG. 2 shows an example battery constructed in accordance with the principles of the present disclosure;

FIG. 3 is a block diagram of some entities in the system according to some embodiments of the present disclosure;

FIG. 4 shows an example process overview according to some embodiments of the present disclosure;

FIG. 5 shows an example diagnostic strategy according to some embodiments of the present disclosure;

FIG. 6 shows example elements of diagnostic accuracy, reliability, and battery life according to some embodiments of the present disclosure;

FIG. 7 is chart showing example cell voltage values that are usable for SoF prediction using a cell-level monitoring approach according to some embodiments of the present disclosure;

FIG. 8 is a chart showing other example cell voltage values that are usable for SoF prediction according to some embodiments of the present disclosure; and

FIG. 9 is a flowchart of an example method according to some embodiments of the present disclosure.

### DETAILED DESCRIPTION

Before describing in detail exemplary embodiments, it is noted that the embodiments reside primarily in combinations of apparatus components and processing steps related to determining a process and/or steps for performing battery diagnostics (e.g., determining battery parameters, failures, battery states, etc.). Accordingly, the system and method components have been represented where appropriate by conventional symbols in the drawings, showing only those specific details that are pertinent to understanding the embodiments of the present disclosure so as not to obscure the disclosure with details that will be readily apparent to those of ordinary skill in the art having the benefit of the description herein.

As used herein, relational terms, such as “first” and “second,” “top” and “bottom,” and the like, may be used solely to distinguish one entity or element from another entity or element without necessarily requiring or implying any physical or logical relationship or order between such entities or elements. The terminology used herein is for the purpose of describing particular embodiments only and is not intended to be limiting of the concepts described herein. As used herein, the singular forms “a”, “an” and “the” are intended to include the plural forms as well, unless the context clearly indicates otherwise. It will be further understood that the terms “comprises,” “comprising,” “includes” and/or “including” when used herein, specify the presence of stated features, integers, steps, operations, elements, and/or components, but do not preclude the presence or addition of one or more other features, integers, steps, operations, elements, components, and/or groups thereof.

In some embodiments, the term “parameter” refers to any parameter related to a battery (and/or its components), battery performance, battery management, operation, vehicle parameters, device systems parameters, etc., as well as performance, management, operation, etc., of the device in which the battery is installed. In some embodiments the parameter may be an electrical parameter such as power, voltage, current, state of charge (SoC), resistance (e.g., battery resistance), voltage (e.g., cell voltage, open circuit voltage (OCV)) and/or any other parameter such as temperature, pressure, frequency parameter (e.g., frequency of a pulse, frequency at which an operation mode is on and/or off and/or activated and/or deactivated), etc. A frequency parameter may refer to a time parameter such as the time a pulse is on or off, the time an operation mode is on/off and/or activated/deactivated. A parameter threshold may refer to a threshold associated with a parameter.

In some embodiments, the term capability is used and may refer to the capability of the battery to provide voltage, current, power, state of charge, or any other parameter that may be used (such as by a vehicle) to perform a function such as a safety function. The capability may be an indication which may be transmitted and may include information (such as parameters, time and/or range for performing the safety function). The capability may be included in a message, signaling, notification, etc. A component receiving the capability or indication may use the included information to perform actions such as display the information for a user such as a driver of the vehicle, manage operation of systems powered by the battery, reduce power consumption, etc.

A battery health condition may refer to any condition associated with a battery (and/or devices, systems, components associated with the battery such as health of the battery and/or of a vehicle/vehicle system). A battery health condition may include a failure (e.g., a catastrophic failure of a battery/system, a potential failure, a condition associated with a potential failure, triggered system failures, battery pack failure, fail to start/operate vehicle, etc.), a degradation condition (e.g., inability to meet a user/functional/specification requirement such as when a parameter is under/over a predetermined threshold), an internal short circuit, an internal resistance value being under a predetermined threshold (e.g. indicating a short circuit condition), etc.

An operation mode (e.g., power consumption mode) may refer to one or more modes of operating a battery and/or battery management system (BMS) and/or associated vehicle and/or associated system and/or associated device. The operation mode may be based on one parameter such state of charge of the battery. The operation mode may comprise a normal mode, a sleep mode, a shutdown mode, a doze mode, a low power consumption mode, etc.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

In embodiments described herein, the joining term, “in communication with” and the like, may be used to indicate electrical or data communication, which may be accomplished by physical contact, induction, electromagnetic radiation, radio signaling, infrared signaling or optical signaling, for example. One having ordinary skill in the art will appreciate that multiple components may interoperate, and modifications and variations are possible of achieving the electrical and data communication.

In some embodiments, the general description elements in the form of “one of A and B” corresponds to A or B. In some embodiments, at least one of A and B corresponds to A, B or AB, or to one or more of A and B. In some embodiments, at least one of A, B and C corresponds to one or more of A, B and C, and/or A, B, C or a combination thereof.

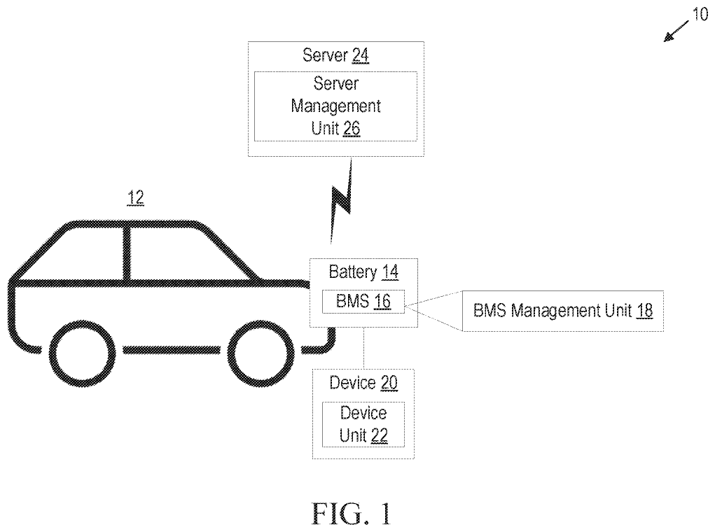

Referring now to the drawing figures, in which like elements are referred to by like reference numerals, there is shown in FIG. 1 a diagram of a system 10, according to an embodiment, which comprises one or more vehicles 12, e.g., a car, motorcycle, scooter, golf cart, light utility vehicle, etc. The vehicle 12 comprises battery 14 for powering at least one function of vehicle 12. In some embodiments, battery 14 may be a lead-acid battery that includes one or more energy storage modules/cells. Although a lead-acid battery is described herein, the teachings described herein are equally applicable to other battery types. Battery 14 may include one or more batteries such as a first battery 14a, second battery 14b, third battery 14c, fourth battery 14d, etc., e.g., electrically connected (e.g., in parallel, series, etc.) as part of a battery pack. Although battery 14 is shown in conjunction with a vehicle 12, battery 14 is not limited as such and may be used in conjunction with any other component (e.g., such as to power any other system component).

Battery 14 includes battery management system (BMS) 16 that is configured to perform one or more battery management functions described herein. In some embodiments, the BMS 16 may measure/determine certain battery parameters, e.g., resistance (e.g., battery resistance), voltage (e.g., cell voltage), current, state of charge (SoC), a time parameter, a frequency parameter, etc., and transmit/receive data (and/or signals such as control signals) to/from another system/device. A BMS 16 is configured to include a BMS management unit 18 that may be configured to perform one or more functions as described herein such as determining one or more parameters, steps, and/or processes associated with battery diagnostics.

System 10 may further include device 20 comprising device unit 22 that may be configured to perform one or more functions as described herein such as provide one or more device functions, e.g., a device configurable to monitor and/or control and/or diagnose battery 14 and/or BMS 16, etc. Device 20 may be physically and/or electrically connected to one or more components of system 10 such as battery 14 and/or BMS 16, e.g., to display an indication of parameter determined by BMS 16. System 10 may also include server 24 comprising server management unit 26, which may be configured to perform one or more functions as described herein such as determining a diagnostic parameter, battery life, a battery health condition and/or operation mode of battery 14, schedule a maintenance action based on the determined battery health condition and/or operation mode, etc.

It is contemplated that one or more entities of system 10 are in communication with each other via one or more of wireless communication, power communication, wired communication, etc. For example, vehicle 12, battery 14, device 20, and server 24 may communicate with each other directly or indirectly using wireless communication, power communication, wired communication, etc. Further, while it may be assumed in one or more embodiments that there is not data or signal communication between battery 14 and vehicle 12, the embodiments described herein are equally applicable to vehicles 12 where there are at least some data/signal communications between battery 14 and vehicle 12. Further, although battery 14 is shown as part of vehicle 12 may be a standalone battery, removably couplable to any component of system 10 such as vehicle 12, etc.

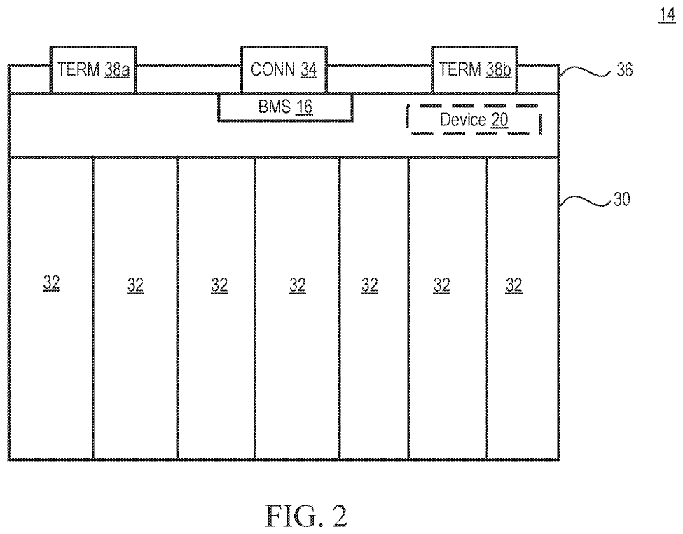

FIG. 2 shows an example battery 14 constructed in accordance with the principles of the present disclosure. Battery 14 includes a housing 30 into which one or more battery components may be positioned. The components may be electrically interconnected (not shown in the FIGS), such as via an electrically conductive bus bar system which electrically interconnects the components in an electrically serial, electrically parallel or combination of electrically serial and parallel manner, depending on the intended voltage and current requirements.

A battery monitoring system (BMS) 16 may be included. BMS 16 may include a monitoring connector 34 that allows for a removable external connection any other component of system 10 (e.g., to the vehicle's data bus, to some other communication device, device 20, etc.) and/or internal connection, e.g., any components of battery 14 and/or BMS 16 and/or device 20. Connector 34 may be comprised in BMS 16 and/or device 20. In some embodiments, connector 34 may be configured to removably couple and/or connect (electrically, physically) to another connector. The monitoring connector 34 can, in some embodiments, be integrated with the housing 30, such as in a cover 36 of the housing 30. Battery 14 also includes terminals, such as a positive terminal 38a and a negative terminal 38b (collectively referred to as terminals 38) to provide the contact points for electrical connection of the battery 14 (e.g., to device 20 such as to power device 20, to the vehicle 12 such as to provide power to the vehicle and/or BMS 16 such as to power BMS 16). Terminals 38 may be arranged to protrude through housing 30, such as protruding through cover 36. Terminals 38 may be electrically connected to the bus bars inside housing 30 and/or directly connected to cells 32 (bus bars and direct connection not shown).

Further, battery 14 may be arranged to provide many power capacities and physical sizes, and to operate under various parameters and parameter ranges. It is also noted that implementations of battery 14 some can be scaled to provide various capacities. For example, in some embodiments, the power capacity of battery 14 can range from 25 Ah to 75 Ah. It is noted, however, that this range is merely an example, and that it is contemplated that embodiments of battery 14 can be arranged to provide less than a 25 Ah capacity or more than a 75 Ah capacity. Power capacity scaling can be accomplished, for example, by using higher or lower power capacity cells 32 in the housing 30, and/or by using fewer or more cells 32 in the housing 30. In some embodiments, battery 14 may be incorporated as part of a vehicle where battery power is needed. Other electrical parameters of the battery 14 can be adjusted/accommodated by using cells 32 that may cumulatively have the desired operational characteristics, e.g., current, voltage, charge, charging capacity/rate, discharge rate, etc. Thermal properties can be managed based on cell 32 characteristics, the use of heat sinks and/or thermal energy discharge plates, etc., within or external to the housing 30. Further, BMS 16 and/or device 20 may be connected to at least one of the cells such as to determine/measure at least one parameter of battery 14 and/or cells 32.

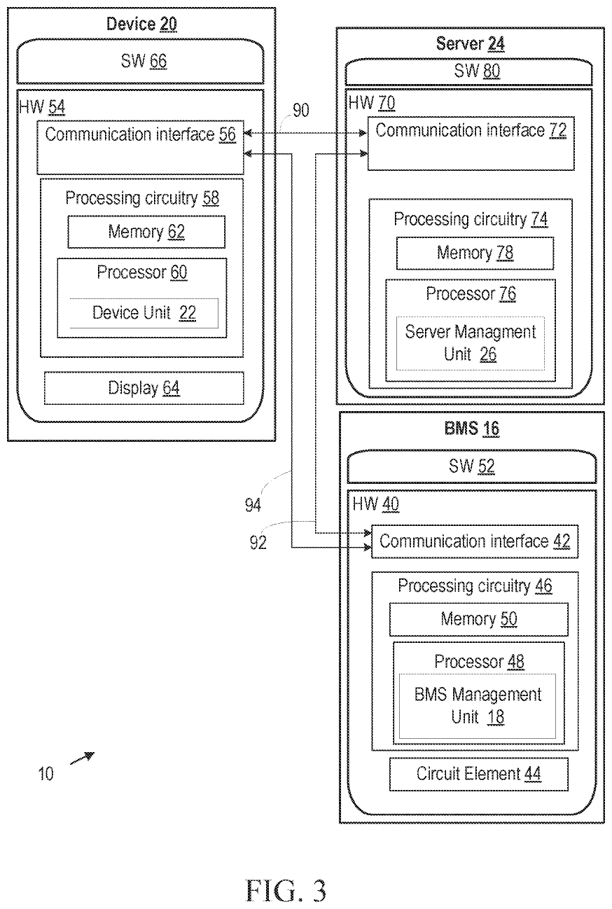

Example implementations, in accordance with an embodiment, of BMS 16, device 20, and server 24 discussed in the preceding paragraphs will now be described with reference to FIG. 3. BMS 16 may have hardware 40 that may include a communication interface 42 that is configured to communicate with one or more entities in system 10 via wired and/or wireless communication. The communication may be protocol based communications.

The hardware 40 includes processing circuitry 46. The processing circuitry 46 may include a processor 48 and memory 50. In particular, in addition to or instead of a processor, such as a central processing unit, and memory, the processing circuitry 46 may comprise integrated circuitry for processing and/or control, e.g., one or more processors and/or processor cores and/or FPGAs (Field Programmable Gate Array) and/or ASICs (Application Specific Integrated Circuitry) adapted to execute instructions. The processor 48 may be configured to access (e.g., write to and/or read from) memory 50, which may comprise any kind of volatile and/or nonvolatile memory, e.g., cache and/or buffer memory and/or RAM (Random Access Memory) and/or ROM (Read-Only Memory) and/or optical memory and/or EPROM (Erasable Programmable Read-Only Memory). Hardware 40 may also comprise one or more circuit elements 44 such as resistors, capacitors, inductors, diodes, transistors, ground connections, source elements, sink elements, etc. Circuit elements 44 may be arranged in any configuration or connection such as series, parallel, combinations thereof, etc.

Thus, the BMS 16 may further comprise software 52, which is stored in, for example, memory 50, or stored in external memory (e.g., database, etc.) accessible by the BMS 16. The software 52 may be executable by the processing circuitry 46.

The processing circuitry 46 may be configured to control any of the methods and/or processes described herein and/or to cause such methods, and/or processes to be performed, e.g., by BMS 16. The processor 48 corresponds to one or more processors 48 for performing BMS 16 functions described herein. The BMS 16 includes memory 50 that is configured to store data, programmatic software code and/or other information described herein. In some embodiments, the software 52 may include instructions that, when executed by the processor 48 and/or processing circuitry 46, causes the processor 48 and/or processing circuitry 46 to perform the processes described herein with respect to BMS 16. For example, the processing circuitry 46 of the BMS 16 may include BMS management unit 18 that is configured to perform any step and/or task and/or process and/or method and/or feature described in the present disclosure, e.g., determining one or more parameters, steps, and/or processes associated with battery diagnostics. While BMS management unit 18 is illustrated as being part of BMS 16, BMS management unit 18 and associated functions described herein may be implemented in a device separate from BMS 16 such as in battery 14 or another device.

Device 20 may have hardware 54 that may include a communication interface 56 that is configured to communicate with one or more entities in system 10 (and/or outside of system 10) via wired and/or wireless communication. The communication may be protocol based communication. Device 20 may also be configured to electrically connect to battery 14, e.g., to power device 20 and/or receive at least one parameter (and/or parameter data) from battery 14 and/or display the at least one parameter.

The hardware 54 includes processing circuitry 58. The processing circuitry 58 may include a processor 60 and memory 62. In particular, in addition to or instead of a processor, such as a central processing unit, and memory, the processing circuitry 58 may comprise integrated circuitry for processing and/or control, e.g., one or more processors and/or processor cores and/or FPGAs (Field Programmable Gate Array) and/or ASICs (Application Specific Integrated Circuitry) adapted to execute instructions. The processor 60 may be configured to access (e.g., write to and/or read from) memory 62, which may comprise any kind of volatile and/or nonvolatile memory, e.g., cache and/or buffer memory and/or RAM (Random Access Memory) and/or ROM (Read-Only Memory) and/or optical memory and/or EPROM (Erasable Programmable Read-Only Memory).

Device 20 may further comprise software 66, which is stored in, for example, memory 62, or stored in external memory (e.g., database, etc.) accessible by the device 20. The software 66 may be executable by the processing circuitry 58.

The processing circuitry 58 may be configured to control any of the methods and/or processes described herein and/or to cause such methods, and/or processes to be performed, e.g., by device 20. The processor 60 corresponds to one or more processors 60 for performing device 20 functions described herein. The device 20 includes memory 62 that is configured to store data, programmatic software code and/or other information described herein. In some embodiments, the software 66 may include instructions that, when executed by the processor 60 and/or processing circuitry 58, causes the processor 60 and/or processing circuitry 58 to perform the processes described herein with respect to device 20. For example, the processing circuitry 58 of device 20 may include device unit 22 configured to perform any step and/or task and/or process and/or method and/or feature described in the present disclosure, e.g., determining one or more parameters, steps, and/or processes associated with battery diagnostics. Device 20 may also include display 64 configured to display an indication associated with a measured/determined at least one parameter, e.g., associated with battery 14. The at least one parameter may include state of charge, voltage, current, etc. Display 64 may comprise a light such as a light emitting diode (LED), a monitor, a screen, and/or any other type of display.

In some embodiments, device 20 and/or any of its components such as display 64 may be comprised in BMS 16 (and/or battery 14) and/or be powered by BMS 16 (and/or battery 14).

Further, server 24 includes hardware 70, and the hardware 70 may include a communication interface 72 for performing wired and/or wireless communication with BMS 16 and/or device 20 and/or any other device. For example, communication interface 72 of server 24 may communicate with communication interface 56 of device 20 via communication link 90. In addition, communication interface 72 of server 24 may communicate with communication interface 42 of BMS 16 via communication link 92. Similarly, communication interface 42 may communicate with communication interface 56 via communication link 94. At least one of communication links 90, 92, 94 may refer to a wired/wireless connection (such as WiFi, Bluetooth, etc.).

In the embodiment shown, the hardware 70 of server 24 includes processing circuitry 74. The processing circuitry 74 may include a processor 76 and a memory 78. In particular, in addition to or instead of a processor, such as a central processing unit, and memory, the processing circuitry 74 may comprise integrated circuitry for processing and/or control, e.g., one or more processors and/or processor cores and/or FPGAs (Field Programmable Gate Array) and/or ASICs (Application Specific Integrated Circuitry) adapted to execute instructions. The processor 76 may be configured to access (e.g., write to and/or read from) the memory 78, which may comprise any kind of volatile and/or nonvolatile memory, e.g., cache and/or buffer memory and/or RAM (Random Access Memory) and/or ROM (Read-Only Memory) and/or optical memory and/or EPROM (Erasable Programmable Read-Only Memory).

Thus, the server 24 further has software 80 stored internally in, for example, memory 78, or stored in external memory (e.g., database, etc.) accessible by the server 24 via an external connection. The software 80 may be executable by the processing circuitry 74. The processing circuitry 74 may be configured to control any of the methods and/or processes described herein and/or to cause such methods, and/or processes to be performed, e.g., by server 24. Processor 76 corresponds to one or more processors 76 for performing server 24 functions described herein. The memory 78 is configured to store data, programmatic software code and/or other information described herein. In some embodiments, the software 80 may include instructions that, when executed by the processor 76 and/or processing circuitry 74, causes the processor 76 and/or processing circuitry 74 to perform the processes described herein with respect to server 24. For example, processing circuitry 74 of server 24 may include server management unit 26 that is configured to perform one or more server 24 functions as described herein, e.g., determining one or more parameters, steps, and/or processes associated with battery diagnostics.

In some embodiments, device 20 may be comprised in a BMS 16 and/or battery 14 (as shown in FIG. 2) and/or vehicle 12 and/or be standalone. In some other embodiments, device 20 may be configured to perform any BMS function.

Although FIGS. 1 and 3 show one or more “units” such as BMS management unit 18, device unit 22, server management unit 26 as being within a respective processor, it is contemplated that these units may be implemented such that a portion of the unit is stored in a corresponding memory within the processing circuitry. In other words, the units may be implemented in hardware, software or in a combination of hardware and software within the processing circuitry.

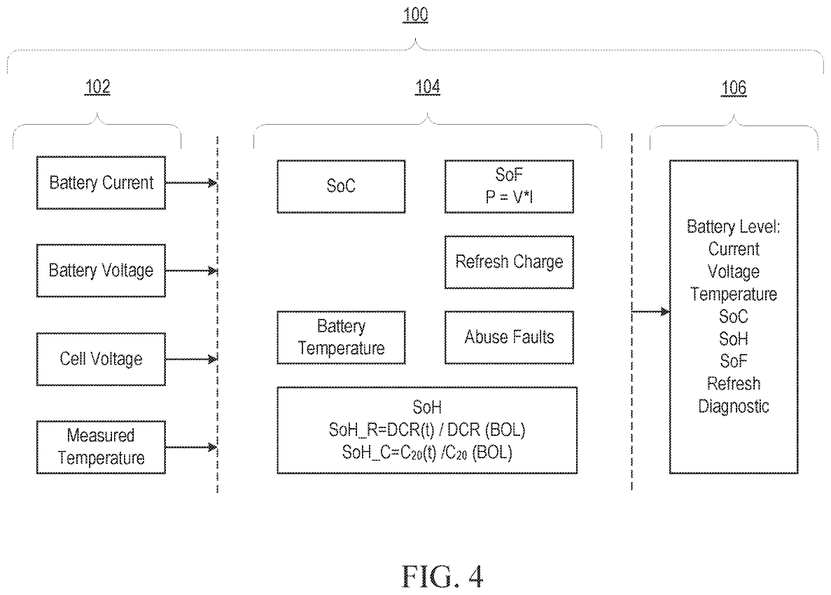

FIG. 4 shows example elements of a process (e.g., algorithm, method) to determine one or more parameters. The example process may be performed by any one of the components of system 10 (e.g., BMS 16) and may comprise receiving one or more input parameters 102 and/or determining parameters 104 and/or providing one or more output parameters 106. Input parameters 102 may include battery current, battery voltage, cell voltage, temperature (e.g., measured temperatures), etc. Input parameters 102 such as voltage, current, temperature, etc. may be measured per cell 32 such as via leads connected to each cell. The method may comprise determining parameters 104 such as state of charge (SoC), state of function (SoF), refresh charge, battery temperature, abuse faults, state of health (SoH), e.g., based on the input parameters 102. Output parameters 106 may include current, voltage, temperature, SoC, SoH, SoF, refresh charge, diagnostics, etc., e.g., based on the parameters 104. In some embodiments, BMS 16 may be configured to perform one or more steps/blocks shown in FIG. 4, which may include determining and/or communicating to another device one or more of parameters 104 (and/or input parameters 102 and/or output parameters 106), e.g.: SoC, SoF, battery temperature, SoH, refresh charge, abuse faults, etc., e.g., based on the inputs. BMS 16 may be configured to provide the outputs (e.g., by determining and/or communicating at least one of the outputs). SoH may include SoH Resistance (SoH_R) and/or SoH Capacity (SoH_C). SoH_R may depend on DCR(t) and/or DCR (BOL), where DCR may refer to direct current resistance, and BOL refers to beginning of life of the battery. C₂₀ (t) may refer to capacity over time and C₂₀ (BOL) may refer to capacity at BOL.

In some embodiments, functional safety targets may be determined, which may include determining mean time between failures, battery failure probability, sudden failures, progress failures, accelerated failures, factors that induce sudden failures, factors that induce accelerated failures, plots of progress failures, etc.

Mean time between failures may be based on the following condition:

$$\frac{1}{False\_Pass \_Rate} * Battery Life > Target$$

Further, a diagnostic coverage may be determined which may include determining false pass rate as follows:

$$False\_Pass \_Rate = {\sum }_{i = 1}^{N} False\_Pass {\_Rate}_{{F}_{m o d e = i}} * P ( {F}_{M o d e} = i )$$

With respect to battery failure probability (P), P may be determined as follows:

$$P ( {F}_{M o d e} = i )$$

$${\sum }_{i = 1}^{N} P ( {F}_{M o d e} = i ) = 1$$

False_Pass_Rate may refer to the percentage of the times a negative event is being identified as positive out of all actual negative events.

P(F_{Mode}=i) may refer to the probability of failure mode (F_{Mode}) i which is one of the total N types of battery failure modes.

Further, a battery may experience failures such as a sudden failure, a progress failure, an accelerated failure. Factors that may induce sudden failures may include vibration and/or impact (e.g., leads to breakage), high current (e.g., leads to melt down), rapid self-disassembly, etc. A progress failure may be a failure occurring following a linear rate of decay which associated with battery resistance increase or capacity loss. The battery variability of this type of failure tends to remain consistent throughout the battery life. Therefore the error of the diagnostic algorithm tends to remain consistent. In some embodiments, progress failures may include failures associated with capacity of the battery. Further, factors that may induce accelerated failures include internal soft short, severe loss of active material, etc.

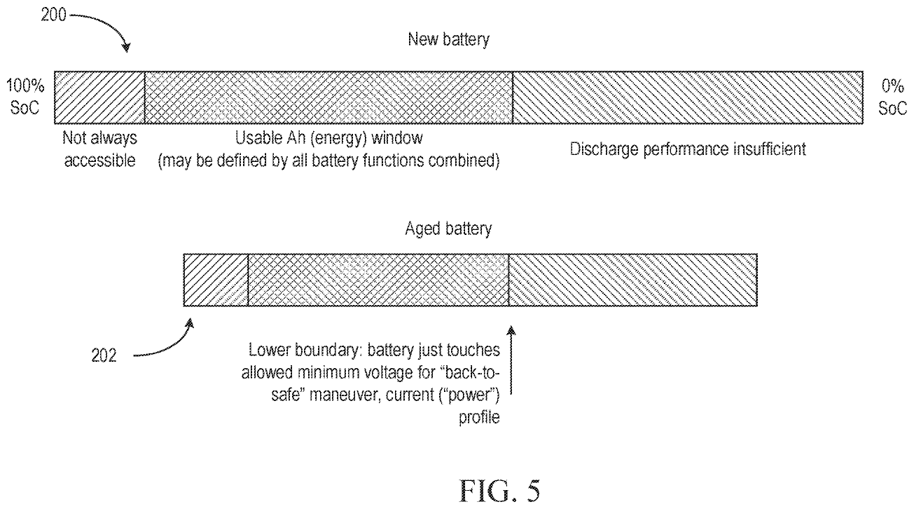

FIG. 5 shows an example battery diagnostics for functional safety. Windows 200 are shown for a full SoC range of a new battery, and windows 202 are shown for another SoC range of an aged battery. If a battery is relevant for functional safety (i.e., which may provide one or more safety functions), requirements may be generated such as battery selection and sizing, operating strategy, battery diagnostics, hardware failure requirements. With respect to battery selection and sizing, capacity and cold crank amperage (CCA) may be selected such that a usable energy window is sufficient. Test methods may be performed and maps of pulse power performance as a function of time and SoC may be used. With respect to the operating strategy, safe operation of the battery 14 may be required, while making certain functions (e.g., safety functions) available during the usable energy window. In some embodiments, BMS diagnostics outputs such as SOF may be used as an input.

In some embodiments, a diagnostic strategy for failure modes and/or battery internal short circuit failure may be used. While battery internal short circuit may not manifest as a sudden failure, battery 14 may still be able to perform cranking pulse (e.g., provide a startup power) as long as it is being recently charged. However, battery failure may be detected by a no start condition only after the battery 14 has been allowed to sit without charge for some time and allowed the cell with the short to discharge.

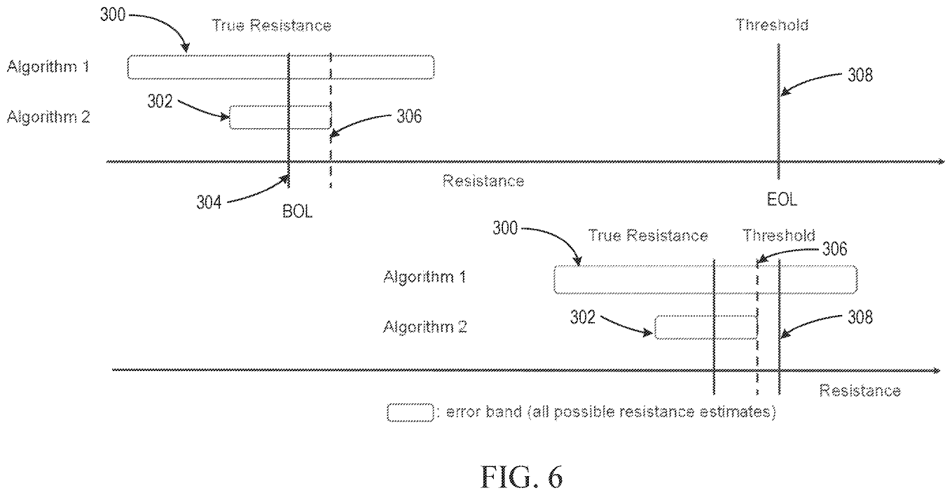

FIG. 6 shows example elements of diagnostic accuracy, reliability, battery life, including a comparison of two algorithms that can be performed by the BMS. For example, a first algorithm has a greater error band 300 than the error band 302 of the second algorithm. Both error bands may be determined based on the true resistance 304 and an offset 306. The true resistance 304 at the beginning of life (BOL) of battery 14 may be farther from the threshold 308 associated with the end of life (EOL) of battery 14. The first algorithm may be less likely to fail (false pass) since it results in replacing battery 14 earlier, even before reaching the threshold 308. An error margin may be added to help the “accurate” algorithm to reduce the early false pass rate. The “less accurate” algorithm (e.g., the second algorithm) may cause battery to be replaced too early.

In some embodiments, failure diagnosis dependency associated with progressive failures is provided, where OCV may be associated with acid density and/or SoC, an initial voltage drop may be associated with internal resistance and/or SoH, and a voltage drop immediately above the cutoff voltage may be associated with active material and another SoH. Further, BMS 16 may determine that SoC (and/or an associated failure) may be associated with or is based on acid density. Temperature and SoF (and/or an associated failure) may be associated with any dependency of failure diagnosis. SoH_R (and/or an associated failure) may be associated with and/or be determined based on internal resistance. SoH_C (and/or an associated failure) may be associated with and/or be determined based on information about active materials of battery 14.

In some embodiments, a startup parameter and/or pull over parameter ratios may be determined by BMS 16 based on SoC for cycle and resting aging. For example, the resistance of battery 14 may be determined from vehicle startup load and may be sufficient to predict battery resistance for emergency peak pulse. The ratios may correspond to different cycle aging and resting aging periods of battery 14. In some embodiments, the ratios of startup parameter to the pull over parameter can be estimated by the algorithm running in the BMS 16. The pull over parameter may be predicted. Any one of the estimation or the prediction of the pull over parameter may be established through testing and implemented in the BMS 16. In some other embodiments, the ratios of startup parameter to the pull over parameter (which is to be predicted, e.g., as a function of temperature or aging) can be established through testing and implemented in the BMS 16. Further, relative pull-over resistance values across time may be determined for different temperatures (e.g., −20 C, 25 C, 50 C). The impact of resistance at each temperature to a prediction model may be determined.

In some embodiments, cell-to-cell deviations may be measured or determined. The cell-to-cell deviations may be a cause for triggering accelerated failures. Short circuit conditions may occur in one cell 32 (or more). The single cell OCV over time, single cell voltage for each cycle, and single cell voltage over time may be determined or analyzed for each cell 32 to identify soft short circuits or other cell performance condition. In some embodiments, cell 32 voltage measurements may be more sensitive to accelerated performance failures triggered by soft short(s) in a single cell 32. For example a battery 14 may have multiple cells 32 (e.g., sixth lead acid battery cells), where battery performance is limited by the lowest performing cell 32 (i.e., the sixth cell), which may be identified by detecting cell-to-cell deviations. In some embodiments, cell-to-cell deviations may be detected by using the capability of the BMS to measure one or more parameters of each cell 32, i.e., employing cell-level monitoring.

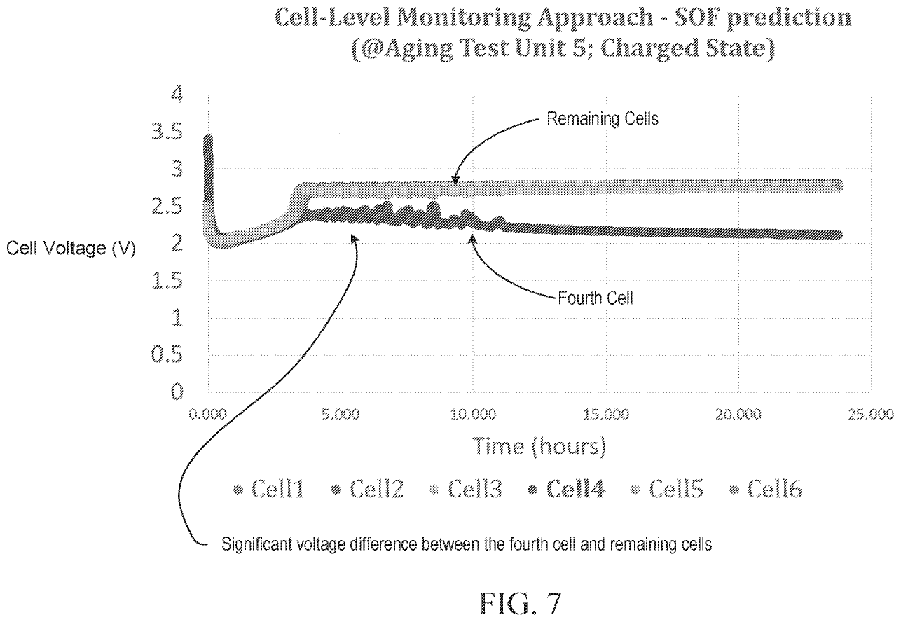

FIG. 7 shows example cell voltage values that are usable for SoF prediction using a cell-level monitoring approach according to one or more embodiments of the present disclosure. The cell-level monitoring approach can detect battery 14 issues such as at an aging test unit (e.g., device). A voltage difference of the fourth cell 32 may be detected such as in comparison with the plot associated with the cell voltage of other cells 32. That is, comparing the parameter of a cell with the parameter of another cell may allow for early detection of a SoF of battery 14 (e.g., whether battery will be able to perform a safety function) and also predict SoF at a future time. In addition, normal vehicle usage may be sufficient (e.g., to perform the cell-level monitoring), a special discharge (e.g., deep discharge of 50% or more) may not be needed as in conventional systems.

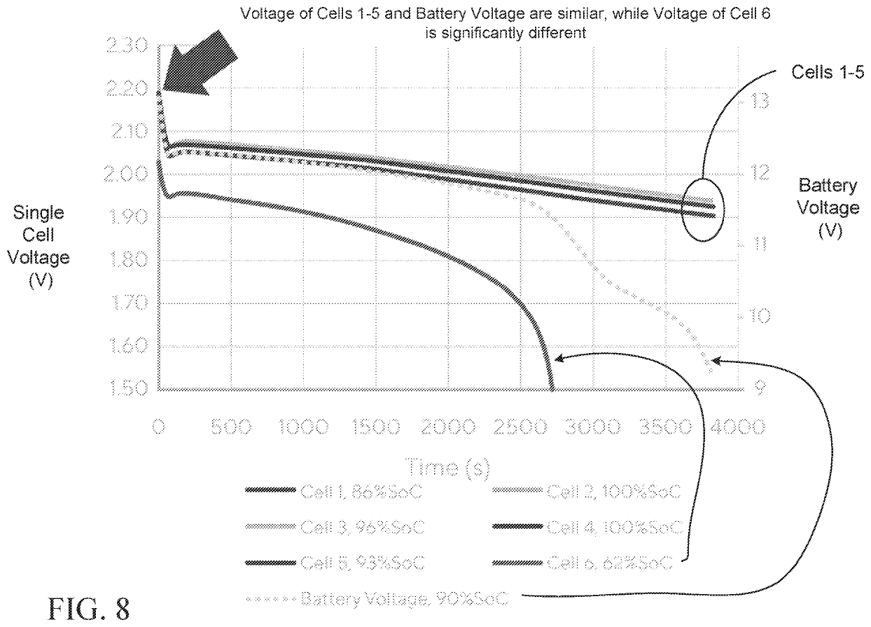

FIG. 8 shows other example cell voltage values that are usable for SoF prediction using a cell-level monitoring approach. In conventional systems (e.g., traditional approach), there may not be significant battery voltage difference between battery voltage readings associated with a “good battery” and readings associated with a battery 14 with that has a cell short-circuit until after a period of time. That is, issues associated with cell short-circuit conditions may not be detectable using traditional methods, e.g., until after thirty minutes or more. However, by using cell-level monitoring, the battery 14 with the cell short-circuit” (i.e., the sixth cell) can advantageously be diagnosed much earlier (e.g., after 100 seconds, before vehicle emergency usage, etc.). That is, cell-level monitoring allows the battery to provide a safety function such as pulling over to a safe zone while still using the battery 14 before the cell condition causes the condition of the battery 14 to reach a catastrophic condition, e.g., where the single cell voltage of the sixth cell is under 1.6V, and the battery voltage (Y axis on the right) is 10V (+/−an offset) at 3500 seconds.

By performing cell-level monitoring, single cell voltage associated with a cell 32 that has a predetermined condition may be read and compared to other cell voltages. The comparison may be used to determine a state of the battery 14 (e.g., including a predicted state, a diagnosis, etc.). That is, determining that a cell 32 exhibits a predetermined condition (e.g., the sixth cell 32 showing a predetermined deviation of single cell voltage with respect to other cells 32 of the same battery 14) allows to determine that the battery 12 has a short-circuit (e.g., internal short-circuit in the sixth cell 32) such as without having to wait for a predetermined discharge level (e.g., SoC less than 50%).

Thus, one or more embodiments provide determining a process and/or steps for performing battery diagnostics (e.g., determining battery parameters, failures, battery states, etc.) such as without having to wait for the battery to discharge to a predetermined level. The diagnosis may be based on the discovery of a correlation between startup signals (e.g., information, data, measurements) and pull-over signals. Further, one or more embodiments provide a process that has higher sensitivity (e.g., when compared to conventional processes) to accelerated failures caused by cell performance deviations among cells 32 connected in series.

In some embodiments, the capability of the BMS 16 to measure one or more parameters of each cell 32 can be leveraged or used by BMS 16 (or any other component of system 10) to determine and/or monitor (per cell 32) the correlation between signals associated with the startup (e.g., of the engine of vehicle 12) and a pull-over parameter (e.g., power or energy required for safely pulling vehicle 12 over, or to perform any other safety function). In some embodiments, the power required for performing the safety function such as pulling over may be higher than the startup power. For example, the power required for pulling over may be four or five times greater than the power required for starting the engine. That is, although the battery 14 may have sufficient SoC (or voltage, or other parameter) for starting the engine, it may not have sufficient SoC (or voltage, or other parameter) for performing a safety function. For example, the battery voltage may drop below a predetermined threshold that is the minimum for voltage for performing the safety function, such as where the battery voltage drops below 9.2V, i.e., the minimum voltage required to power vehicle communication systems that may be used during an emergency call. Thus, by determining the capability of the battery 14 to provide one or more output parameters usable for performing a safety function, BMS 16 is capable of predicting whether the battery 14 can provide one or more output parameters (e.g., voltage, power, etc.) and/or vehicle 12 can perform the safety function (e.g., pulling over, turning emergency lights on, provide emergency calling, etc.).

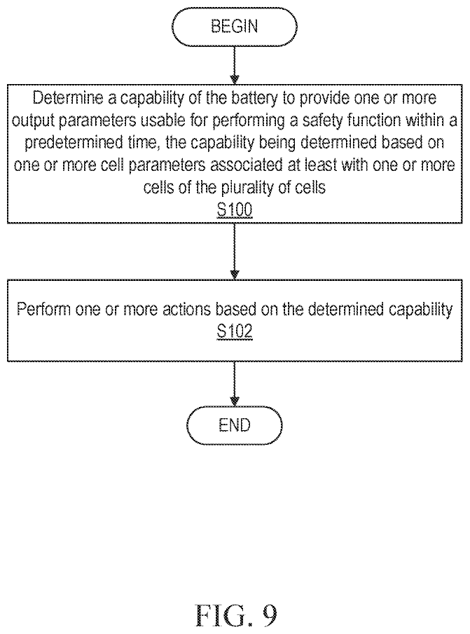

FIG. 9 shows a flowchart of an example method. The method may be implemented in BMS 16 (or any other component of system 10). BMS 16 may be comprised in a battery 14 that has a plurality of cells 32. The BMS 16 is electrically couplable to each cell 32 of the plurality of cells 32 and is configured to, via processing circuitry 46 and/or processor 48 and/or BMS management unit 18 and/or circuit element 44 and/or communication interface 42, determine (Block S100) a capability of the battery 14 to provide one or more output parameters usable for performing a safety function within a predetermined time. The capability is determined based on one or more cell parameters associated at least with one or more cells 32 of the plurality of cells 32. The BMS 16 is further configured to, via processing circuitry 46 and/or processor 48 and/or BMS management unit 18 and/or circuit element 44 and/or communication interface 42, perform (Block S102) one or more actions based on the determined capability.

In some embodiments, the BMS 16 is further configured to determine the one or more output parameters of the battery 14 based on the one or more cell parameters associated at least with the one or more cells 32 of the plurality of cells 32, obtain an output parameter threshold, and compare the determined one or more output parameters to the obtained output parameter threshold to the determine the capability of the battery 14.

In some other embodiments, the one or more cell parameters include one or more of a battery current, a battery voltage, a cell voltage, a temperature parameter.

In some embodiments, the one or more output parameters includes one or more of a battery current, a battery voltage, a battery temperature, battery state of charge, battery state of health, battery state of function.

In some other embodiments, one or both the capability and the one or more output parameters are determined based on a prediction model.

In some embodiments, the one or more output parameters include a resistance associated with the one or more cells 32 at a predetermined battery temperature, and the BMS 16 is further configured to determine an increase of the resistance over time to determine the capability of the battery 14.

In some other embodiments, the BMS 16 is further configured to perform a state of function prediction based the one or more cell parameters to determine the capability of the battery 14.

In some embodiments, the BMS 16 is further configured to one or more of compare a first cell parameter of the one or more cell parameters with a predetermined cell parameter threshold, determine a difference between the first cell parameter and a second cell parameter of the one or more cell parameters, perform the state of function prediction based on one or both of the comparison and the determined difference.

In some other embodiments, the BMS 16 is further configured to determine a correlation between a third cell parameter and a fourth cell parameter of the one or more cell parameters to determine the capability of the battery 14, where the third cell parameter is associated with a start-up signal, the fourth cell parameter corresponds to performing the safety function, and the correlation is usable to determine the capability of the battery 14.

In some embodiments, the safety function includes safely pulling over and stopping a vehicle 12 within the predetermined time.

In some other embodiments, the safety function includes using, within the predetermined time, a vehicle system that is electrically couplable to the battery 14.

In some embodiments, the one or more actions include one or more of identifying a cell 32 that is underperforming, causing recharging of the identified cell 32, and transmitting an indication indicating the capability of the battery 14.

As will be appreciated by one of skill in the art, the concepts described herein may be embodied as a method, data processing system, computer program product and/or computer storage media storing an executable computer program. Accordingly, the concepts described herein may take the form of an entirely hardware embodiment, an entirely software embodiment or an embodiment combining software and hardware aspects all generally referred to herein as a “circuit” or “module.” Any process, step, action and/or functionality described herein may be performed by, and/or associated to, a corresponding module, which may be implemented in software and/or firmware and/or hardware. Furthermore, the disclosure may take the form of a computer program product on a tangible computer usable storage medium having computer program code embodied in the medium that can be executed by a computer. Any suitable tangible computer readable medium may be utilized including hard disks, CD-ROMs, electronic storage devices, optical storage devices, or magnetic storage devices.

Some embodiments are described herein with reference to flowchart illustrations and/or block diagrams of methods, systems and computer program products. It will be understood that each block of the flowchart illustrations and/or block diagrams, and combinations of blocks in the flowchart illustrations and/or block diagrams, can be implemented by computer program instructions. These computer program instructions may be provided to a processor of a general purpose computer (to thereby create a special purpose computer), special purpose computer, or other programmable data processing apparatus to produce a machine, such that the instructions, which execute via the processor of the computer or other programmable data processing apparatus, create means for implementing the functions/acts specified in the flowchart and/or block diagram block or blocks.

These computer program instructions may also be stored in a computer readable memory or storage medium that can direct a computer or other programmable data processing apparatus to function in a particular manner, such that the instructions stored in the computer readable memory produce an article of manufacture including instruction means which implement the function/act specified in the flowchart and/or block diagram block or blocks.

The computer program instructions may also be loaded onto a computer or other programmable data processing apparatus to cause a series of operational steps to be performed on the computer or other programmable apparatus to produce a computer implemented process such that the instructions which execute on the computer or other programmable apparatus provide steps for implementing the functions/acts specified in the flowchart and/or block diagram block or blocks.

It is to be understood that the functions/acts noted in the blocks may occur out of the order noted in the operational illustrations. For example, two blocks shown in succession may in fact be executed substantially concurrently or the blocks may sometimes be executed in the reverse order, depending upon the functionality/acts involved. Although some of the diagrams include arrows on communication paths to show a primary direction of communication, it is to be understood that communication may occur in the opposite direction to the depicted arrows.

Computer program code for carrying out operations of the concepts described herein may be written in an object oriented programming language such as Python, Java® or C++. However, the computer program code for carrying out operations of the disclosure may also be written in conventional procedural programming languages, such as the “C” programming language. The program code may execute entirely on the user's computer, partly on the user's computer, as a stand-alone software package, partly on the user's computer and partly on a remote computer or entirely on the remote computer. In the latter scenario, the remote computer may be connected to the user's computer through a local area network (LAN) or a wide area network (WAN), or the connection may be made to an external computer (for example, through the Internet using an Internet Service Provider).

Many different embodiments have been disclosed herein, in connection with the above description and the drawings. It will be understood that it would be unduly repetitious and obfuscating to literally describe and illustrate every combination and subcombination of these embodiments. Accordingly, all embodiments can be combined in any way and/or combination, and the present specification, including the drawings, shall be construed to constitute a complete written description of all combinations and subcombinations of the embodiments described herein, and of the manner and process of making and using them, and shall support claims to any such combination or subcombination.

It will be appreciated by persons skilled in the art that the present embodiments are not limited to what has been particularly shown and described herein above. In addition, unless mention was made above to the contrary, it should be noted that all of the accompanying drawings are not to scale. A variety of modifications and variations are possible in light of the above teachings and the following claims.

1. A battery management system, BMS, of a battery comprising a plurality of cells, the BMS being electrically couplable to each cell of the plurality of cells, the BMS being configured to:
determine a capability of the battery to provide one or more output parameters usable for performing a safety function within a predetermined time, the capability being determined based on one or more cell parameters associated at least with one or more cells of the plurality of cells; and
perform one or more actions based on the determined capability.

2. The BMS of claim 1, wherein the BMS is further configured to:
determine the one or more output parameters of the battery based on the one or more cell parameters associated at least with the one or more cells of the plurality of cells;
obtain an output parameter threshold; and
compare the determined one or more output parameters to the obtained output parameter threshold to the determine the capability of the battery.

3. The BMS of claim 1, wherein the one or more cell parameters include one or more of a battery current, a battery voltage, a cell voltage, a temperature parameter.

4. The BMS of claim 1, wherein the one or more output parameters includes one or more of a battery current, a battery voltage, a battery temperature, battery state of charge, battery state of health, battery state of function.

5. The BMS of claim 1, wherein one or both the capability and the one or more output parameters are determined based on a prediction model.

6. The BMS of claim 5, wherein the one or more output parameters include a resistance associated with the one or more cells at a predetermined battery temperature, and the BMS is further configured to determine an increase of the resistance over time to determine the capability of the battery.

7. The BMS of claim 1, wherein the BMS is further configured to:
perform a state of function prediction based the one or more cells parameters to determine the capability of the battery.

8. The BMS of claim 7, wherein the BMS is further configured to one or more of:
compare a first cell parameter of the one or more cell parameters with a predetermined cell parameter threshold;
determine a difference between the first cell parameter and a second cell parameter of the one or more cell parameters;
perform the state of function prediction based on one or both of the comparison and the determined difference.

9. The BMS of claim 1, wherein the BMS is further configured to:
determine a correlation between a third cell parameter and a fourth cell parameter of the one or more cell parameters to determine the capability of the battery, the third cell parameter being associated with a start-up signal, the fourth cell parameter corresponding to performing the safety function, the correlation being usable to determine the capability of the battery.

10. The BMS of claim 1, wherein the safety function includes one or both of:
safely pulling over and stopping a vehicle within the predetermined time; and
using, within the predetermined time, a vehicle system that is electrically couplable to the battery.

11. (canceled)

12. The BMS of claim 1, wherein the one or more actions include one or more of:
identifying a cell that is underperforming;
causing recharging of the identified cell; and
transmitting an indication indicating the capability of the battery.

13. A battery comprising battery management system, BMS, and a plurality of cells, the BMS being electrically coupled to each cell of the plurality of cells, the BMS being configured to:
determine a capability of the battery to provide one or more output parameters usable for performing a safety function within a predetermined time, the capability being determined based on one or more cell parameters associated at least with one or more cells of the plurality of cells; and
perform one or more actions based on the determined capability.

14. The battery of claim 13, wherein one or both the capability and the one or more output parameters are determined based on a prediction model; and wherein the one or more output parameters include a resistance associated with the one or more cells at a predetermined battery temperature, and the BMS is further configured to determine an increase of the resistance over time to determine the capability of the battery.

15. (canceled)

16. The battery of claim 13, wherein the BMS is further configured to:
perform a state of function prediction based the one or more cell parameters to determine the capability of the battery.

17. The battery of claim 16, wherein the BMS is further configured to one or more of:
compare a first cell parameter of the one or more cell parameters with a predetermined cell parameter threshold;
determine a difference between the first cell parameter and a second cell parameter of the one or more cell parameters; and
perform the state of function prediction based on one or both of the comparison and the determined difference.

18. The battery of claim 13, wherein the BMS is further configured to:
determine a correlation between a third cell parameter and a fourth cell parameter of the one or more cell parameters to determine the capability of the battery, the third cell parameter being associated with a start-up signal, the fourth cell parameter corresponding to performing the safety function, the correlation being usable to determine the capability of the battery.

19. The battery of claim 13, wherein the safety function includes, within the predetermined time, one or more of:
safely pulling over;
stopping a vehicle; and
using a vehicle system that is electrically couplable to the battery.

20. The battery of claim 13, wherein the one or more actions include one or more of:
identifying a cell that is underperforming;
causing recharging of the identified cell; and
transmitting an indication indicating the capability of the battery.

21. A system comprising a vehicle and a battery positionable within the vehicle, the battery comprising a battery management system, BMS, and a plurality of cells, the BMS being electrically coupled to each cell of the plurality of cells, the BMS being configured to:
determine a capability of the battery to provide one or more output parameters usable for performing a safety function within a predetermined time, the capability being determined based on one or more cell parameters associated at least with one or more cells of the plurality of cells; and
perform one or more actions based on the determined capability.

22. The system of claim 21, wherein:
the safety function includes, within the predetermined time, one or more of:
safely pulling the vehicle over;
stopping the vehicle; and
using a vehicle system that is electrically coupled to the battery; and
wherein the one or more actions include one or more of:
identifying a cell that is underperforming;
causing recharging of the identified cell; and
transmitting an indication indicating the capability of the battery.

23. (canceled)

24. (canceled)
